(19) United States
(12) Patent Application Publication
(10) Pub. No.: US 2021/0263327 A1
(43) Pub. Date: Aug. 26, 2021

(54) DISPLAY STRUCTURE

(71) Applicant: KABUSHIKI KAISHA TOKAI RIKA DENKI SEISAKUSHO, Aichi (JP)

(72) Inventor: Mitsuru NARUSE, Aichi (JP)

(73) Assignee: KABUSHIKI KAISHA TOKAI RIKA DENKI SEISAKUSHO, Aichi (JP)

(21) Appl. No.: 17/255,207

(22) PCT Filed: Jun. 25, 2019
(86) PCT No.: PCT/JP2019/025110

§ 371 Date: Dec. 22, 2020

(30) Foreign Application Priority Data
Jun. 27, 2018 (JP) 2018-122015

(51) Int. Cl. G02B 27/28; G02B 5/02; H01L 33/58

(52) U.S. Cl. CPC G02B 27/281; H01L 2933/0091; H01L 33/58; G02B 5/0278

(57) ABSTRACT

A first polarization member has a first polarization axis and allows passage of light having a polarization component parallel to the first polarization axis. A second polarization member has a second polarization axis and allows passage of light having a polarization component parallel to the second polarization axis. The first and the second polarization members are arranged such that a direction of the first polarization axis and a direction of the second polarization axis are non-parallel. The first polarization member includes a portion provided with a first pattern that allows passage of light regardless of a direction of a polarization component. The second polarization member includes a portion provided with a second pattern that allows passage of light regardless of a direction of a polarization component. The portion where the first pattern is provided and the portion where the second pattern is provided are filled with optical resins.

### TECHNICAL FIELD

The present disclosure relates to a display structure for allowing a user to visually recognize a plurality of patterns.

### BACKGROUND ART

JP S61-025002 Y discloses a display switching apparatus that uses a polarization member as an example of such a display structure.

The polarization member has a polarization axis that extends in a specific direction. Light having a polarization component parallel to the polarization axis is allowed to pass through the polarization member. In the following description, such light will be referred to as first polarized light. Light having a polarization component that is not parallel to the polarization axis is not allowed to pass. In the following description, such light will be referred to as second polarized light.

A polarization member that does not allow the second polarized light to pass therethrough by absorbing the second polarized light is referred to as an absorptive polarization member. The absorptive polarization member can be formed, for example, by stretching a polyvinyl alcohol (PVA) film substrate impregnated with an iodine compound in a specific direction and subjecting the substrate to a crosslinking treatment.

In the display switching apparatus, a plurality of polarization plates having different directions of polarization axes are arranged on a path of light emitted from a light source. Different transparent patterns are formed in the plurality of polarization plates. A display structure is formed by the plurality of polarization plates each having a transparent pattern formed therein. The term “transparent” in the following description means a property of allowing passage of both the first polarized light and the second polarized light. The term “pattern” in the following description is meant to include a graphic, a character, a symbol, a mark, a picture, and the like.

As a method for forming the above-described pattern in the absorptive polarization member, it is known that a part of the substrate corresponding to a shape of the pattern is removed.

In the display switching apparatus, a polarization direction of incident light is switched so as to form the second polarized light for a specific polarization plate. Incident light only passes through a region where a pattern is formed in the specific polarization plate. As a result, the pattern is visually recognized by the user. The polarization direction of the incident light is changed, so that the “specific polarization plate” can be changed, and a pattern provided for display to the user can be switched.

### SUMMARY OF INVENTION

In the display structure, since the plurality of polarization plates are arranged on the path of the light emitted from the light source, there is a position where the plurality of patterns overlap one another when viewed from a direction along the path. An amount of light that passes through may differ between a position where the plurality of patterns overlap one another and a position where the plurality of patterns do not overlap. Accordingly, desired visibility may not be obtained for the plurality of patterns visually recognized by the user through the display structure.

Thus, it is sought to obtain desired visibility for the plurality of patterns visually recognized by the user through the display structure.

One aspect for satisfying the above-described requirements provides a display structure including:

a first polarization member having a first polarization axis, and configured to allow passage of light having a polarization component parallel to the first polarization axis and block passage of light having a polarization component non-parallel to the first polarization axis;

a second polarization member having a second polarization axis, and configured to allow passage of light having a polarization component parallel to the second polarization axis and block passage of light having a polarization component non-parallel to the second polarization axis; and

an optical resin,

in which the first polarization member and the second polarization member are arranged such that a direction of the first polarization axis and a direction of the second polarization axis are non-parallel,

in which the first polarization member includes a portion provided with a first pattern configured to allow passage of light regardless of a direction of a polarization component,

in which the second polarization member includes a portion provided with a second pattern configured to allow passage of light regardless of a direction of a polarization component, and

in which at least the portion being provided with the first pattern and the portion being provided with the second pattern are filled with the optical resin.

In the display structure having the above-described configuration, there may be a position where an edge of a pattern of one polarization member overlaps a pattern of the other polarization member when viewed from an arrangement direction of the first polarization member and the second polarization member. At the position, there is a possibility that luminance unevenness of a pattern is visually recognized. The portion where the first pattern is provided and the portion where the second pattern is provided are filled with the optical resin, so that the optical resin is disposed at the position when viewed from the arrangement direction of the first polarization member and the second polarization member. The inventor has found that such a configuration prevents luminance unevenness of a pattern. Therefore, desired visibility is obtained for a plurality of patterns visually recognized by a user through the display structure.

### BRIEF DESCRIPTION OF DRAWINGS

FIG. 1 illustrates a configuration of a display apparatus according to a first embodiment.

FIG. 2 is a diagram illustrating an operation principle of the display apparatus.

FIG. 3 illustrates a partial configuration of the display apparatus.

FIG. 4 illustrates a configuration of a display apparatus according to a second embodiment.

### DESCRIPTION OF EMBODIMENTS

Examples of embodiments will be described in detail below with reference to the accompanying drawings. In each drawing using the description hereinafter, a scale of each member is appropriately adjusted in order to show each member in a recognizable size.

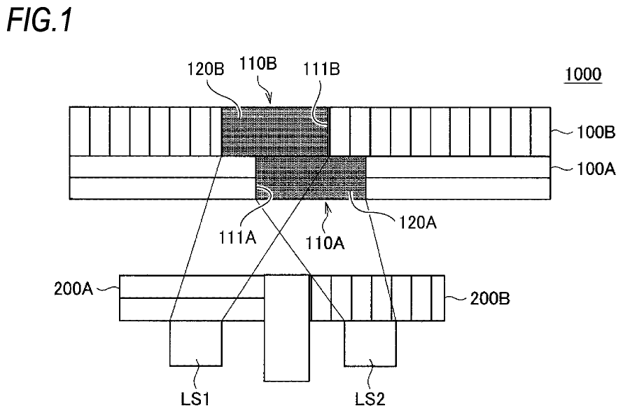

FIG. 1 illustrates a configuration of a display apparatus 1000 according to a first embodiment. The display apparatus 1000 is driven by electric power supplied from an internal power supply such as a battery or electric power supplied from an external power supply such as a commercial power supply.

The display apparatus 1000 includes a first polarization member 100A and a second polarization member 100B. The first polarization member 100A and the second polarization member 100B build a display structure.

The first polarization member 100A includes a substrate having a first polarization axis. The first polarization member 100A allows passage of light having a polarization axis parallel to the first polarization axis. The first polarization member 100A does not allow passage of light having a polarization axis non-parallel to the first polarization axis.

The first polarization member 100A may be an absorptive polarization member. In this case, the first polarization member 100A allows the light having the polarization axis parallel to the first polarization axis to pass therethrough and absorbs the light having the polarization axis non-parallel to the first polarization axis.

A first pattern 110A having an arbitrary shape is formed in the first polarization member 100A. When the first polarization member 100A is an absorptive polarization member, the first pattern 110A is formed by removing a part of the substrate by punching processing or laser processing. It is desirable that the processing is performed such that a burr does not occur at an edge of the pattern. Light incident on the first pattern 110A is allowed to pass therethrough regardless of a polarization direction thereof.

The first polarization member 100A may be a reflective polarization member. In this case, the first polarization member 100A allows the light having the polarization axis parallel to the first polarization axis to pass therethrough and reflects the light having the polarization axis non-parallel to the first polarization axis. The reflective polarization member can be formed by vapor-depositing a metal on a film substrate having a nano grid structure. The film substrate can be formed by triacetylcellulose (TAC), cyclo-olefin polymer (COP), or the like. Examples of the metal to be vapor-deposited include aluminum, silver, and chrome.

When the first polarization member 100A is a reflective polarization member, the first pattern 110A can be formed by removing, by punching processing or laser processing, a portion where the metal is vapor-deposited.

The second polarization member 100B includes a substrate having a second polarization axis. The second polarization member 100B allows passage of light having a polarization axis parallel to the second polarization axis. The second polarization member 100B does not allow passage of light having a polarization axis non-parallel to the second polarization axis.

The second polarization member 100B may be an absorptive polarization member. In this case, the second polarization member 100B allows the light having the polarization axis parallel to the second polarization axis to pass therethrough and absorbs the light having the polarization axis non-parallel to the second polarization axis.

A second pattern 110B having an arbitrary shape is formed in the second polarization member 100B. When the second polarization member 100B is an absorptive polarization member, the second pattern 110B is formed by removing a part of the substrate by punching processing or laser processing. It is desirable that the processing is performed such that a burr does not occur at an edge of the pattern. Light incident on the second pattern 110B is allowed to pass therethrough regardless of a polarization direction thereof.

The second polarization member 100B may be a reflective polarization member similar to the first polarization member 100A. In this case, the second polarization member 100B allows the light having the polarization axis parallel to the second polarization axis to pass therethrough and reflects the light having the polarization axis non-parallel to the second polarization axis. When the second polarization member 100B is a reflective polarization member, the second pattern 110B can be formed by removing, by punching processing or laser processing, a portion where the metal is vapor-deposited.

The first polarization member 100A and the second polarization member 100B are arranged side by side along a traveling direction of incident light. The first polarization member 100A and the second polarization member 100B are arranged such that a direction of the first polarization axis and a direction of the second polarization axis are non-parallel.

The first polarization member 100A and the second polarization member 100B are arranged such that the first polarization axis and the second polarization axis have the above-described relationship, so that polarized light allowed to pass through the first polarization member 100A is not allowed to pass through the second polarization member 100B. Similarly, polarized light allowed to pass through the second polarization member 100B is not allowed to pass through the first polarization member 100A.

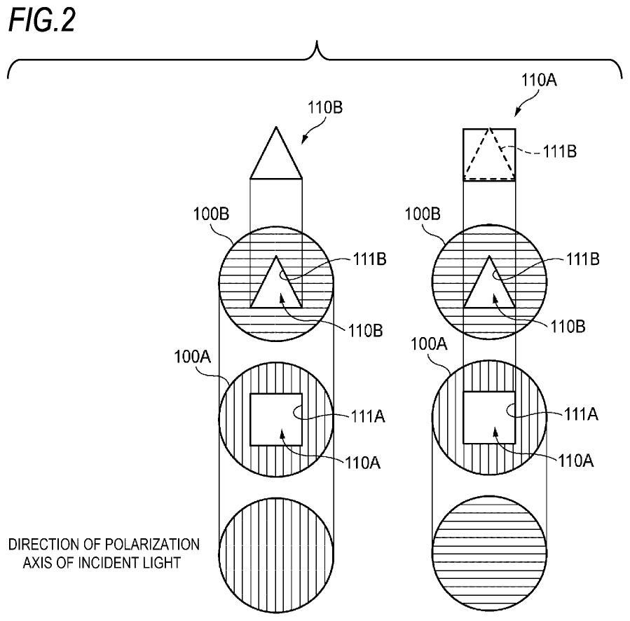

That is, by appropriately setting a polarization state of light incident on the display structure build by the first polarization member 100A and the second polarization member 100B, three display states listed below can be achieved. A principle thereof will be described with reference to FIG. 2.

(1) Display of Second Pattern 110B

A polarization axis of light incident on the display structure is set so as to have a component parallel to the first polarization axis of the first polarization member 100A, so that the incident light passes through the first polarization member 100A. Since a polarization axis of polarized light that passes through the first polarization member 100A intersects the second polarization axis of the second polarization member 100B, the polarized light does not pass through the second polarization member 100B. However, the second pattern 110B formed in the second polarization member 100B allows passage of the polarized light.

Therefore, light that passes through the second pattern 110B can be visually recognized by the user. In other words, a shape of the second pattern 110B can be provided for display to the user.

(2) Display of First Pattern 110A

The polarization axis of the light incident on the display structure is set so as to have a component parallel to the second polarization axis of the second polarization member 100B, so that the incident light does not pass through the first polarization member 100A. However, the first pattern 110A formed in the first polarization member 100A allows passage of the polarized light. Since a polarization axis of polarized light that passes through the first pattern 110A is parallel to the second polarization axis of the second polarization member 100B, the polarized light passes through the second polarization member 100B.

Therefore, light that passes through the first pattern 110A can be visually recognized by the user. In other words, a shape of the first pattern 110A can be provided for display to the user.

(3) Display of First Pattern 110A and Second Pattern 110B

The polarization axis of the light incident on the display structure is set so as to have a component parallel to the first polarization axis of the first polarization member 100A and a component parallel to the second polarization axis of the second polarization member 100B, so that the second pattern 110B is provided for display as described in above-described (1), and the first pattern 110A is provided for display as described in above-described (2).

Accordingly, the display structure including the plurality of polarization members each having a pattern formed therein can switch a pattern provided for display to the user.

In the configuration illustrated in FIG. 1, an edge 111A of the first pattern 110A overlaps the second pattern 110B when viewed from a direction of incident light. Similarly, an edge 111B of the second pattern 110B overlaps the first pattern 110A when viewed from an arrangement direction of the first polarization member 100A and the second polarization member 100B. Accordingly, at a position where an edge of a pattern of one polarization member overlaps a pattern of the other polarization member when viewed from the arrangement direction of the plurality of polarization members, luminance unevenness of the pattern may be visually recognized.

For example, when the first pattern 110A illustrated in FIG. 2 is visually recognized, luminance unevenness corresponding to a shape of the edge 111B of the second pattern 110B may occur.

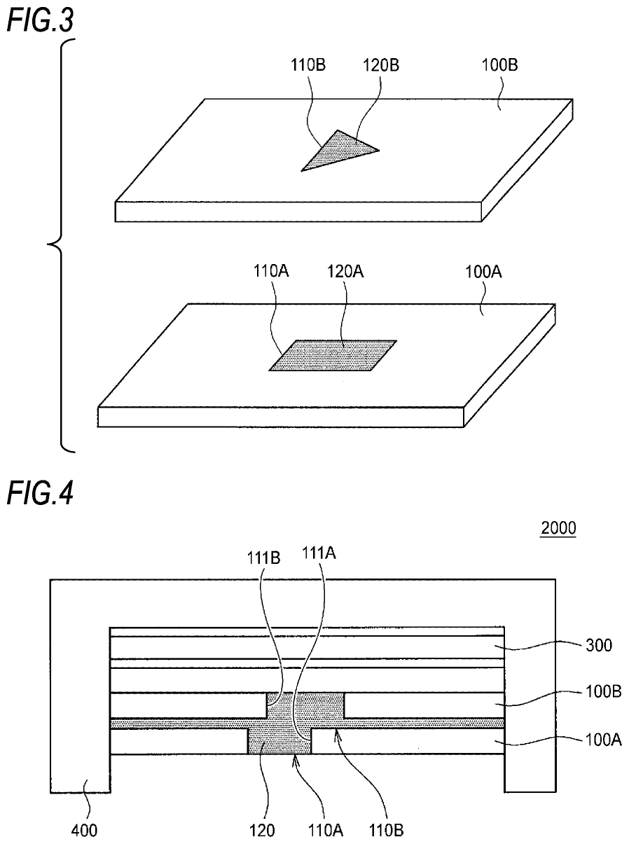

As illustrated in FIG. 3, in the present embodiment, a portion of the first polarization member 100A where the first pattern 110A is formed is filled with a first optical resin 120A. Similarly, a portion of the second polarization member 100B where the second pattern 110B is formed is filled with a second optical resin 120B.

Each of the first optical resin 120A and the second optical resin 120B has a property of maintaining a polarization state of light that passes therethrough. Since a polarization state is prevented from being destroyed due to deviation of a phase difference, visibility of each pattern is prevented from being lowered.

Accordingly, as illustrated in FIG. 1, an optical resin having the above-described property is disposed at the position where the edge of the pattern of one polarization member overlaps the pattern of the other polarization member when viewed from the arrangement direction of the plurality of polarization members. The inventor has found that luminance unevenness of a pattern that can be visually recognized at the position is prevented by such a configuration. Therefore, desired visibility is obtained for a plurality of patterns visually recognized by a user through the display structure.

An optically clear resin (OCR) can be used as an example of an optical resin having such a property. A silicon-based OCR or an acryl-based OCR can be used.

The OCR is useful in that the OCR can also be used as an optical bonding agent. The OCR is liquid in an initial state, but is cured by irradiation with light having a predetermined wavelength such as ultraviolet rays. The defoamed liquid OCR is used, so that it is possible to fill a portion where a pattern is formed in a polarization member without any gap and firmly bond the cured optical resin to a surrounding substrate.

An optical resin that can be used as the optical bonding agent is not limited to the photocurable resin. A thermosetting resin may also be used.

As illustrated in FIG. 1, the display apparatus 1000 can include a third polarization member 200A. The third polarization member 200A includes a substrate having a third polarization axis. A direction of the third polarization axis is parallel to the direction of the first polarization axis of the first polarization member 100A. Therefore, light that passes through the third polarization member 200A can pass through the substrate of the first polarization member 100A, but cannot pass through the substrate of the second polarization member 100B.

As illustrated in FIG. 1, the display apparatus 1000 can include a fourth polarization member 200B. The fourth polarization member 200B includes a substrate having a fourth polarization axis. A direction of the fourth polarization axis is parallel to the direction of the second polarization axis of the second polarization member 100B. Therefore, light that passes through the fourth polarization member 200B can pass through the substrate of the second polarization member 100B, but cannot pass through the substrate of the first polarization member 100A.

Each of the third polarization member 200A and the fourth polarization member 200B may be an absorptive polarization member or a reflective polarization member.

Light, which passes through at least one of the third polarization member 200A and the fourth polarization member 200B configured in this manner, is allowed to be incident on the display structure built by the first polarization member 100A and the second polarization member 100B, so that any one of the above-described display states (1) to (3) can be selectively achieved. Arrangement of the third polarization member 200A and the fourth polarization member 200B can be appropriately determined as long as passage of the light is enabled before the light is incident on the display structure.

As illustrated in FIG. 1, the display apparatus 1000 can include a first light source LS1 and a second light source LS2. The first light source LS1 is disposed such that emitted light thereof passes through the third polarization member 200A. The second light source LS2 is disposed such that emitted light thereof passes through the fourth polarization member 200B.

Each of the first light source LS1 and the second light source LS2 can be configured with at least one semiconductor light-emitting element that emits light of at least one color. Examples of the semiconductor light-emitting element include a light-emitting diode (LED), a laser diode (LD), and an organic EL element. Each of the first light source LS1 and the second light source LS2 may be a lamp light source such as a halogen lamp. Turning on/off each of the first light source LS1 and the second light source LS2 can be controlled by a processor (not shown) provided in the display apparatus 1000.

According to such a configuration, by controlling light-emitting states of the first light source LS1 and the second light source LS2, any one of the above-described display states (1) to (3) can be selectively achieved.

When light can pass through at least one of the third polarization member 200A and the fourth polarization member 200B prior to being incident on the display structure, a light source that emits the light does not need to be plural. For example, the display apparatus 1000 can include a mechanism that changes a position of a single light source between a first position and a second position. In this case, light emitted from the single light source disposed at the first position passes through the third polarization member 200A, and light emitted from the single light source disposed at the second position passes through the fourth polarization member 200B. Alternatively, the display apparatus 1000 can include a mechanism that disposes at least one of the third polarization member 200A and the fourth polarization member 200B on a path of light emitted from the single light source.

When light can pass through at least one of the third polarization member 200A and the fourth polarization member 200B prior to being incident on the display structure, the light may be supplied from outside of the display apparatus 1000.

FIG. 4 illustrates a configuration of a display structure 2000 according to a second embodiment. Elements substantially the same as constituent elements of the display apparatus 1000 according to the first embodiment are denoted by the same reference numerals, and repetitive description thereof will be omitted.

The display structure 2000 includes the first polarization member 100A, the second polarization member 100B, and an optical resin 120. The optical resin 120 has a property of being usable as an optical bonding agent in addition to a property of maintaining a polarization state of light that passes therethrough. Examples of such an optical resin include OCR.

A portion of the first polarization member 100A where the first pattern 110A is formed and a portion of the second polarization member 100B where the second pattern 110B is formed are filled with the optical resin 120. Further, the optical resin 120 is also filled between the first polarization member 100A and the second polarization member 100B in an arrangement direction. The first polarization member 100A and the second polarization member 100B are bonded by the integrated optical resin 120.

Specifically, the portion of the first polarization member 100A where the first pattern 110A is formed and the portion of the second polarization member 100B where the second pattern 110B is formed are filled with the defoamed liquid OCR. Further, the defoamed liquid OCR is also filled between the first polarization member 100A and the second polarization member 100B in the arrangement direction. Subsequently, by performing a curing treatment, a substrate of the first polarization member 100A and the optical resin 120 are bonded, and a substrate of the second polarization member 100B and the optical resin 120 are bonded. As a result, the first polarization member 100A and the second polarization member 100B are also bonded.

As illustrated in FIG. 4, the display structure 2000 includes a position where an edge of a pattern of one polarization member overlaps a pattern of the other polarization member when viewed from the arrangement direction of the first polarization member 100A and the second polarization member 100B. On the other hand, the optical resin 120 is disposed so as to overlap the position when viewed from the arrangement direction of the first polarization member 100A and the second polarization member 100B. Therefore, luminance unevenness of a pattern that can be visually recognized at the position is prevented. Further, since the first polarization member 100A and the second polarization member 100B are bonded by the integrated optical resin 120, warping or shrinkage of the polarization members that may occur in a high-humidity environment or the like can be prevented, and deformation of the display structure 2000 can be prevented.

As illustrated in FIG. 4, the display structure 2000 can include a diffusion member 300. The diffusion member 300 optically diffuses light that passes through the first polarization member 100A and the second polarization member 100B. Optical diffusion properties may be isotropic or anisotropic.

According to such a configuration, since the light that passes through the first polarization member 100A and the second polarization member 100B is provided for diffusion, a possibility that the luminance unevenness is visually recognized can be further reduced.

The optical resin 120 may be filled between the second polarization member 100B and the diffusion member 300. That is, the first polarization member 100A, the second polarization member 100B, and the diffusion member 300 can be bonded by the integrated optical resin 120. An effect thereof is as described above.

As illustrated in FIG. 4, the display structure 2000 can include a light attenuation member 400. The light attenuation member 400 attenuates intensity of the light that passes through the first polarization member 100A and the second polarization member 100B. As the light attenuation member 400, a smoke material made of a gray-based or black-based visible light cut filter or the like can be used. A shape of the light attenuation member 400 can be appropriately determined.

According to such a configuration, since the light that passes through the first polarization member 100A and the second polarization member 100B is provided for attenuation, a possibility that the luminance unevenness is visually recognized can be further reduced.

When the light attenuation member 400 is provided, the diffusion member 300 can be omitted. In this case, the optical resin 120 can be filled between the second polarization member 100B and the light attenuation member 400. That is, the first polarization member 100A, the second polarization member 100B, and the light attenuation member 400 can be bonded by the integrated optical resin 120. An effect thereof is as described above.

The above-described embodiments are merely examples for facilitating an understanding of the present disclosure. The configurations according to the above-described embodiments can be appropriately modified and improved without departing from the spirit of the present disclosure.

The third polarization member 200A, the fourth polarization member 200B, and at least one light source described with reference to the display apparatus 1000 according to the first embodiment can also be combined with the display structure 2000 according to the second embodiment.

As a part of the description of the present application, the contents of Japanese Patent Application No. 2018-122015 filed on Jun. 27, 2018 are incorporated herein.

1. A display structure comprising:
a first polarization member having a first polarization axis, and configured to allow passage of light having a polarization component parallel to the first polarization axis and block passage of light having a polarization component non-parallel to the first polarization axis;
a second polarization member having a second polarization axis, and configured to allow passage of light having a polarization component parallel to the second polarization axis and block passage of light having a polarization component non-parallel to the second polarization axis; and
an optical resin,
wherein the first polarization member and the second polarization member are arranged such that a direction of the first polarization axis and a direction of the second polarization axis are non-parallel,
wherein the first polarization member includes a portion provided with a first pattern configured to allow passage of light regardless of a direction of a polarization component,
wherein the second polarization member includes a portion provided with a second pattern configured to allow passage of light regardless of a direction of a polarization component, and
wherein at least the portion being provided with the first pattern and the portion being provided with the second pattern are filled with the optical resin.

2. The display structure according to claim 1,
wherein the optical resin is an optically clear resin.

3. The display structure according to claim 1,
wherein the first polarization member and the second polarization member are bonded by the optical resin.

4. The display structure according to claim 1, further comprising:
a third polarization member having a third polarization axis, and configured to allow passage of light having a polarization component parallel to the third polarization axis and block passage of light having a polarization component non-parallel to the third polarization axis; and
a fourth polarization member having a fourth polarization axis, and configured to allow passage of light having a polarization component parallel to the fourth polarization axis and block passage of light having a polarization component non-parallel to the fourth polarization axis,
wherein the third polarization member is disposed such that a direction of the third polarization axis is parallel to the direction of the first polarization axis,
wherein the fourth polarization member is disposed such that a direction of the fourth polarization axis is parallel to the direction of the second polarization axis, and
wherein the first polarization member and the second polarization member are arranged such that light that passes through at least one of the third polarization member and the fourth polarization member is incident.

5. The display structure according to claim 1, further comprising:
at least one light source from which light incident on the first polarization member and the second polarization member is emitted.

6. The display structure according to claim 1, further comprising:
a diffusion member configured to optically diffuse light that passes through the first polarization member and the second polarization member.

7. The display structure according to claim 1, further comprising:
a light attenuation member configured to attenuate intensity of light that passes through the first polarization member and the second polarization member.
